(19) United States
(12) Patent Application Publication
(10) Pub. No.: US 2010/0059103 A1
(43) Pub. Date: Mar. 11, 2010

(54) THIN-FILM TYPE SOLAR CELL MODULE HAVING A REFLECTIVE MEDIA LAYER AND FABRICATION METHOD THEREOF

(76) Inventors: Kun Ho AHN, Seoul (KR); Heon Min Lee, Seoul (KR); Don Hee Lee, Seoul (KR)

Correspondence Address: BIRCH STEWART KOLASCH & BIRCH, PO BOX 747, FALLS CHURCH, VA, 22040-0747, US

(21) Appl. No.: 12/555,325

(22) Filed: Sep. 8, 2009

(30) Foreign Application Priority Data
Sep. 9, 2008 (KR) 10-2008-0088906

(51) Int. Cl. H01L 31/052; H01L 31/18

(52) U.S. Cl. 136/246; 438/72; 257/E21.211; 257/E31.127

(57) ABSTRACT

A thin-film type solar cell module having a reflective media layer capable of optionally transmitting light through intervals formed on the reflective media layer and a method of fabricating the same are described.

This application claims priority to Korean Patent Application No. 10-2008-0088906, filed on Sep. 9, 2008, in the Korean Intellectual Property Office, the entire contents of which are hereby incorporated by reference.

### BACKGROUND OF THE INVENTION

1. Field of the Invention

The present invention generally relates to a thin-film type solar cell module and a method of fabricating the same. More particularly, it relates to a thin-film type solar cell module having a reflective media layer capable of optionally transmitting light through intervals formed on the reflective media layer and a method of fabricating the same.

2. Description of the Related Art

Recently, in order to secure energy resources and overcome global warming, etc., the development and use of eco-friendly alternative energy have actively been made. Such alternative energy may include energy from a solar cell, wind energy, tidal energy and energy from a fuel cell, etc. Among such energy sources, a solar cell, which is an element that converts light energy transmitted from the sun into electric energy to produce energy, has been of interest as the next generation clean energy source.

### SUMMARY OF THE INVENTION

A thin-film type solar cell module comprises a plurality of solar cells that include a lower transparent electrode layer, a solar cell layer, and an upper transparent electrode layer sequentially formed on a lower transparent substrate and that are spaced apart from each other at a predetermined interval; an upper transparent substrate; a reflective media layer that is formed between the solar cell and the upper transparent substrate and includes predetermined openings; and a transparent adhesive layer that bonds the upper transparent substrate to the lower transparent substrate.

A method of manufacturing the thin-film type solar cell module comprises forming a plurality of solar cells that is spaced apart from each other at a predetermined interval on a lower transparent substrate; forming a reflective media layer that is spaced at a predetermined interval on the solar cells; and bonding the lower transparent substrate and the upper transparent substrate by the transparent adhesive layer putting the white reflective media layer there between.

An embodiment of the invention provides a thin-film solar cell module including a plurality of solar cells that include a lower transparent electrode layer, a solar cell layer, and an upper transparent electrode layer sequentially formed on a lower transparent substrate, the lower transparent layer having portions that are spaced apart from each other at a predetermined interval; an upper transparent substrate over the plurality of solar cells; a reflective media layer that is formed between the plurality of solar cell and the upper transparent substrate, the reflective media layer including predetermined openings; and a transparent adhesive layer that bonds the upper transparent substrate to the lower transparent substrate.

An embodiment of the invention provides a method of manufacturing a thin-film solar cell module, including forming a plurality of solar cells that is spaced apart from each other at a predetermined interval on a lower transparent substrate; forming a reflective media layer that is spaced at a predetermined interval on the plurality of solar cells; and bonding the lower transparent substrate and an upper transparent substrate by a transparent adhesive layer putting a reflective media layer there between.

The foregoing is a summary and thus contains, by necessity, simplifications, generalizations and omissions of details; consequently, those skilled in the art will appreciate that the summary is illustrative only and is not intended to be in any way limiting. Other aspects, inventive features, and advantages of the present disclosure, as defined solely by the claims, will become apparent in the non-limiting detailed description set forth below.

### BRIEF DESCRIPTION OF THE DRAWINGS

The above objects, features and advantages of the present invention will become more apparent to those skilled in the related art in conjunction with the accompanying drawings. In the drawings:

FIG. 1 is across-sectional view showing a thin-film type solar cell module structure according to an embodiment of the present invention;

FIGS. 2 to 6 are top views of the thin-film solar cell module structure according to the embodiment of the present invention;

FIGS. 7 to 12 are cross-sectional views showing the process of forming the solar cell on the lower transparent substrate;

FIGS. 13 and 14 are cross-sectional views showing one embodiment of a process of bonding an upper transparent substrate and a lower transparent substrate;

FIGS. 15 and 16 are cross-sectional views showing another embodiment of a process of bonding the upper transparent substrate and the lower transparent substrate; and

FIG. 17 is a cross-sectional view showing the completed thin-film type solar cell module structure.

### DETAILED DESCRIPTION OF THE INVENTION

A thin-film type solar cell module having a white reflective media layer capable of optionally transmitting light and a method of fabricating the same are described.

The technical problems to be addressed by this invention are not limited to the foregoing technical objects, and others not referred to will be understood by those skilled in the art and apparent from the following description.

In order to achieve the above object, a thin-film type solar cell module according to an embodiment of the present invention comprises: a plurality of solar cells that include a lower transparent electrode layer, a solar cell layer, and an upper transparent electrode layer sequentially formed on a lower transparent substrate and that are spaced apart from each other at a predetermined interval; an upper transparent substrate; a reflective media layer that is formed between the solar cell and the transparent substrate and includes predetermined openings; and a transparent adhesive layer that bonds the upper transparent substrate to the lower transparent substrate.

The openings of the reflective media layer may be formed in an interval direction of a unit cell of the solar cells, a direction orthogonal to the interval direction, or both of the interval direction and the orthogonal direction.

The openings of the reflective media layer may be formed in a linear shape, a plurality of circular shapes, or a plurality of polygonal shapes, wherein the polygonal shapes includes a triangle, a quadrangle, and a diamond etc., but the shape is not particularly limited thereto.

The openings of the reflective media layer may be 10% or less, and preferably 5 to 10% or less with respect to a total area of the solar cell module.

The reflective media layer may be formed on the lower surface of the upper transparent substrate or on the upper surface of the solar cells.

In other words, the solar cell module can comprise the reflective media layer bonded on the transparent adhesive layer to be spaced at the inter-solar cell interval on the lower surface of the upper transparent substrate and to face the solar cells.

As the upper transparent substrate, any substrates composed of transparent material among the known substrates can be used. Generally, the upper transparent substrate may be a glass substrate or a transparent polymer sheet to which at least one layer is bonded. As the transparent polymer sheet, a transparent sheet composed of a polymer material can be used, but is not particularly limited. Preferably, the transparent polymer sheet may be composed of polyethylene terephthalate (PET).

Preferably, the lower transparent electrode layer and the upper transparent electrode layer are formed of a transparent conductive oxide (TCO) layer composed of at least one of zinc oxide (ZnO), tin oxide (SnO₂), and indium tin oxide (ITO).

The solar cell may include at least one solar cell layer composed of amorphous silicon or microcrystalline silicon.

The thickness of each layer, which forms the solar cell, may be formed as needed. As a result, the thickness in not particularly limited, but preferably may be 300 to 3000 nm.

The reflective media layer may be composed of a mixture of media and pigment that reflects light having a long wavelength band of 600 nm or more. The media and the pigment may be materials known in the art. As a result, they are not particularly limited.

The reflective media layer 600 could be a white reflective media layer which comprises a mixture of medium and white pigment.

It is preferable that the difference in the refractive index between the pigment and the media may be about 1.5 to 2.0.

The white reflective media layer may be formed using at least one of white paint, white foil and ethyl vinyl acetate (EVA).

The reflective media layer may have a first surface which contacts with the transparent adhesive layer and a second surface which contacts with the upper transparent substrate, wherein the first surface is white and the color of the second surface may be different from that of the first surface.

The intervals of a plurality of the solar cells are not particularly limited, but preferably may be spaced with an interval of 0.5 to 2.0 mm. In the same manner, the interval of the reflective media layer formed to face the solar cell, may also be the same as that of the solar cell or similar thereto.

The transparent adhesive layer is a known material that can bond the solar cell formed on the lower transparent substrate to the upper transparent substrate having the reflective media layer and preferably, is a transparent material. In particular, the material may include ethyl vinyl acetate (EVA) or polyvinyl butyral (PVB).

A method of manufacturing a thin-film type solar cell module according to one embodiment of the present invention comprises: forming a plurality of solar cells that is spaced apart from each other at a predetermined interval on a lower transparent substrate; forming a reflective media layer that is spaced at a predetermined interval on the solar cells; and bonding the lower transparent substrate and the upper transparent substrate by the transparent adhesive layer putting the reflective media layer there between. In other words, the bonding by the transparent adhesive layer bonds the lower transparent substrate on which the solar cells are formed and the upper transparent substrate putting the reflective media layer therebetween.

The reflective media layer may be formed so as to be spaced at the same interval with that of the solar cells. Further, the reflective media layer may be formed in a direction orthogonal to the interval direction of the solar cells.

At this time, the reflective media layer may be formed on the lower surface of the upper transparent substrate or on the upper surface of the transparent adhesive layer.

Preferably, the reflective media layer is formed by one method of a lift-off method, a screen printing method, or an inkjet method.

A method of manufacturing a solar cell module according to another embodiment of the present invention comprises: forming a plurality of solar cells spaced apart from each other at a predetermined interval on a lower transparent substrate; forming a reflective media layer spaced at the same interval as that of the solar cells on a transparent adhesive layer to face the solar cells; and bonding the lower transparent substrate on which the solar cells are formed and the upper transparent substrate by means of the transparent adhesive layer on which the reflective media layer is formed.

Preferably, the solar cell includes at least one solar cell layer composed of amorphous silicon or microcrystalline silicon, and the transparent electrode layer formed on the upper and lower portions of the solar cell layer.

The solar cell module can have stability for a long time and reduce the manufacturing costs by using the white reflective media layer rather than a reflective media layer of metal.

Also, the optionally light-transmissive thin-film type solar cell module can be manufactured since the reflective media layer is formed to be spaced at a predetermined interval corresponding to the solar cell.

Further, one side of the white reflective media layer can be provided with various graphic effects, making it possible to provide the solar cell module with improved aesthetic function.

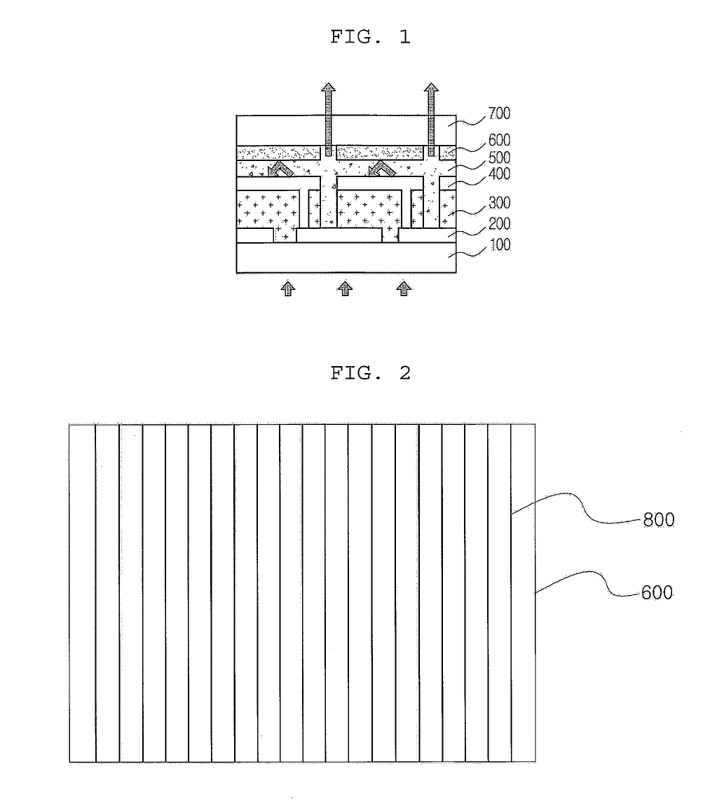

Hereinafter, preferable embodiments according to the present invention will be described with reference to FIGS. 1 to 16.

Terms or words used in the specification and claims should not be construed as limited to a lexical meaning, and should be understood as appropriate notions by the inventor based on that he/she is able to define terms to describe his/her invention in the best way to be seen by others. Therefore, embodiments and drawings described herein are simply exemplary and not exhaustive, and it will be understood that various modifications and equivalents may be made to take the place of the embodiments.

FIG. 1 is a cross-sectional view showing a thin-film type solar cell module structure according to one embodiment of the present invention. Referring to FIG. 1, the thin-film type solar cell module according to one embodiment of the present invention comprises a lower transparent substrate 100, a lower transparent electrode layer 200, a solar cell layer 300, an upper transparent electrode layer 400, a transparent adhesive layer 500, a reflective media layer 600, and an upper transparent substrate 700, all of which are sequentially stacked.

The lower transparent substrate 100 is composed of a transparent material such as glass to have light incident thereon. The lower electrode layer 200 is also composed of a transparent material such as transparent conductive oxide (TCO) including zinc oxide (ZnO), tin oxide (SnO₂), and indium tin oxide (ITO) so that light can be incident thereon and is formed to be separated at a predetermined interval by laser scribing.

The solar cell layer 300 can be formed by stacking a p layer, an i layer, and an n layer that are composed of amorphous silicon, and a p layer, an i layer, and an n layer that are composed of microcrystalline silicon. After the stacking, the solar cell layer 300 is separated by the laser scribing, etc., to deviate (or at positions that deviate) from the spaced position of the lower transparent electrode layer 200.

The upper transparent electrode layer 400 is formed at a thickness of 300 to 300 nm using TCO, etc., as in the lower transparent electrode layer 200 and is separated into a cell unit by being patterned together with the solar cell layer 300 by the laser scribing, etc. At this time, the separated interval may be 0.5 to 2.0 mm.

The upper transparent substrate 700 may be composed of glass etc., like the lower transparent substrate 100. In another embodiment, the upper transparent substrate 700 may be also formed of a transparent polymer sheet to which at least one layer is bonded. Polyethylene terephthalate (PET) may be used as the transparent polymer sheets. If the upper transparent substrate 700 is formed of the PET sheet, it is advantageous that the weight of the solar cell module is lighter and the manufacturing costs decrease.

The reflective media layer 600 is composed of a mixture of a medium and a pigment to be able to improve reflection of a long wavelength band (or a wavelength) of 600 nm or more. According to one embodiment, the reflective media layer 600 could be a white reflective media layer which comprises a mixture of medium and white pigment. For example, white paint, white foil, or ethyl vinyl acetate (EVA) foil may be used as the white reflective media layer 600. At this time, a material wherein the difference in refractive index from the media is 1.5 to 2.0 may be used as the pigment and the pigment in a relative amount of 50 to 100% is mixed with the media. For example, as the pigment, oxide such as titanium oxide (TiO₂), barium sulfate (BaSO₄), a nitride, and a carbide, etc., can be used.

By the reflective media layer 600, long-wavelength light, which is not subjected to photoelectric conversion in the solar cell layer 300, is back reflected to the solar cell layer 300, such that it can be subjected to photoelectric conversion.

According to another embodiment, a portion of the reflective media layer 600 to which light is incident should be formed in a white color, but an opposite portion thereto, that is, a portion contacting the upper transparent substrate 700 may be formed in other colors. Therefore, according to this embodiment, various graphic effects, such as characters, pictures, etc. may be provided on a plane that contacts the upper transparent substrate 700 of the reflective media layer 600, thereby making it possible to provide the solar cell module with excellent aesthetic function.

The reflective media layer 600 is formed to be separated at an interval of 0.5 to 2.0 mm to correspond to the interval of the solar cell, using a lift-off method, a screen printing method, or an inkjet method, etc.

The transparent adhesive layer 500 bonds the lower transparent substrate 100 on which the solar cells are formed to the upper transparent substrate 700 on which the reflective media layer 600 is formed. As the transparent adhesive layer 500, EVA or polyvinyl butyral (PVB) can be used.

As such, the solar cell module of this embodiment rather uses the white reflective media layer 600 instead of the reflective layer of metal such that it can have stability for a long time even when it is exposed to external circumstances and does not use an expensive vacuum apparatus for depositing metal, such that the manufacturing costs of the solar cell module can be reduced. Further, since the white reflective media layer 600 has stronger adhesive strength than a metal material, the solar cell module of the present invention has stability for a long time. In addition, according to this embodiment, since the interval is formed on the white reflective layer 600 at each solar cell unit, the optionally light-transmissive module can be manufactured while the white reflective media layer 600 is used on the solar cell module. The light transmission of the solar cell according to this embodiment may be determined based on the interval of the solar cells, and the interval of the solar cells may be set to meet the characteristics of the solar cell module. On the other hand, according to another embodiment, when the portion of the white reflective media layer 600 contacting the upper transparent substrate 700 is formed in various colors, an aesthetic effect will be increased.

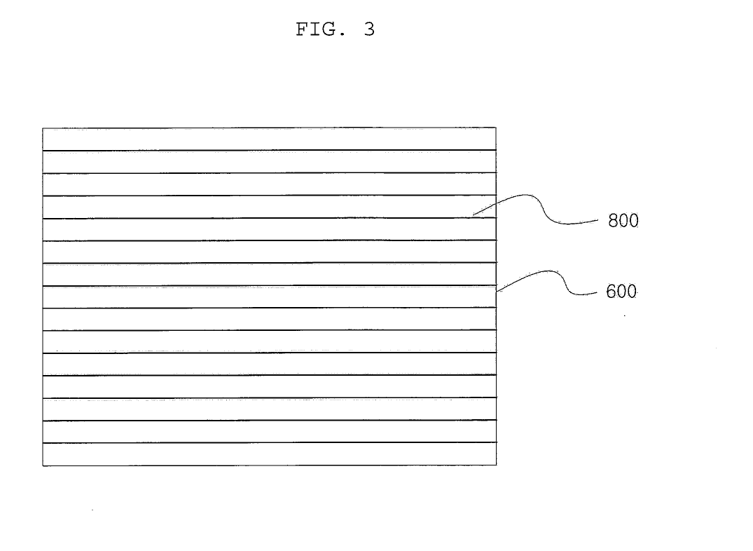

FIGS. 2 to 6 are top views of the thin-film type solar cell module structure according to embodiment of the present invention. Referring to FIG. 2, openings 800 of the reflective media layer 600 are formed in a linear shape in an interval direction of a unit cell of the solar cells, and referring to FIG. 3, the openings 800 of the reflective media layer 600 may be formed in a linear shape in a direction orthogonal to the interval direction. Also, referring to FIG. 4, the openings 800 of the reflective media layer 600 may be formed in both of the interval direction of the solar cells and the direction orthogonal to the interval direction.

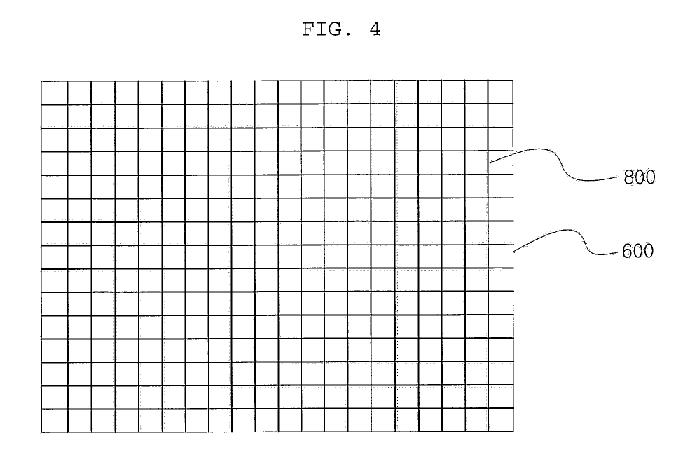

Further, referring to FIGS. 5 and 6, the openings 800 of the reflective media layer 600 are formed in a plurality of circular shapes, or a plurality of polygonal (quadrangular) shapes in an interval direction of the unit cell of the solar cell and a direction orthogonal to the interval direction.

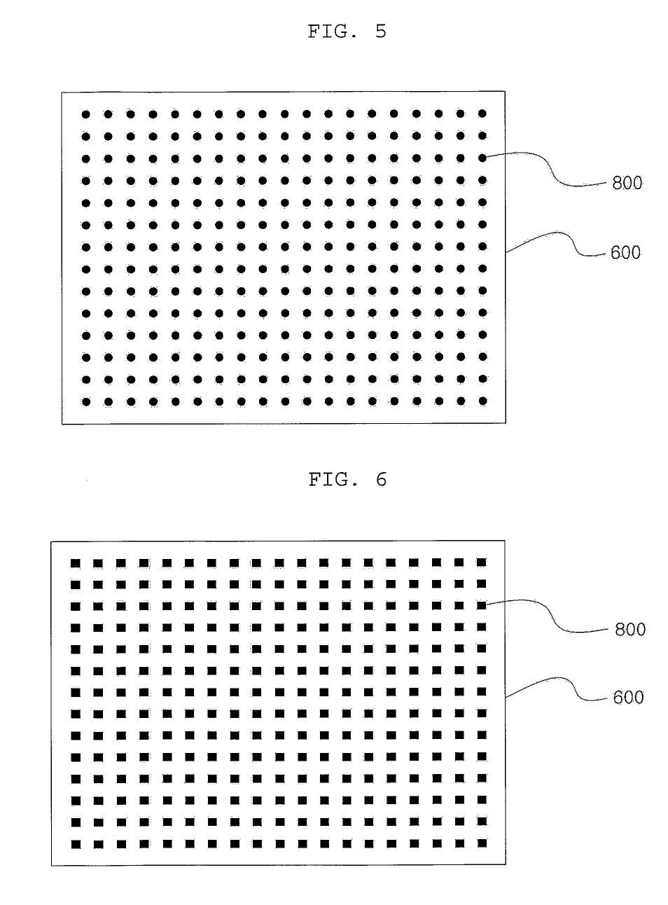

FIGS. 7 to 17 show a method of manufacturing the thin-film type solar cell module according to the embodiment of the present invention shown in FIG. 1. Among these, FIGS. 7 and 8 are cross-sectional views showing a progress of forming the solar cell on the lower transparent substrate 100.

First, as shown in FIG. 7, the lower transparent electrode layer 200 is deposited on the lower transparent substrate 100 and as shown in FIG. 8, the lower transparent electrode layer 200 is separated into a cell unit by laser scribing method or the like, which exposes the lower transparent substrate 100. At this time, the lower transparent electrode layer 200 may be composed of TCO etc., and the separating interval of each cell is formed to be 0.5 to 2.0 mm.

Next, as shown in FIG. 9, the solar cell layer 300 is formed on the lower transparent substrate 100 on which the lower transparent electrode layer 200 is formed. More specifically, the solar cell layer 300 is formed by depositing an amorphous silicon semiconductor layer that is configured of a player, an i layer, and an n layer, by a depositing method, such as plasma enhanced chemical vapor deposition (PECVD), however, the method is not particularly limited thereto. Therefore a plurality of solar cell layers, which are selected from the amorphous silicon semiconducting layer or the microcrystalline silicon semiconductor layer, may be formed.

As the solar cell layer 300, in addition to the amorphous silicon semiconductor layer and the microcrystalline silicon semiconductor layer described above, any materials, which can convert light energy into electrical energy, can be used.

For example, the solar cell layer 300 may be formed by materials containing at least one of single-crystalline silicon, poly silicon, amorphous SiC, amorphous SiN, amorphous SiGe, amorphous SiSn, gallium arsenide (GaAs), aluminium gallium arsenide (AlGaAs), indium phosphide (InP), gallium phosphide (GaP), CIGS (Copper Indium Gallium Selenide), cadmium telluride (CdTe), cadmium sulfide (CdS), copper (I) sulfide (Cu₂S), zinc telluride (ZnTe), lead sulphide (PbS), copper indium diselenide (CulnSe₂; CIS), gallium-antimonide (GaSb), and compounds thereof.

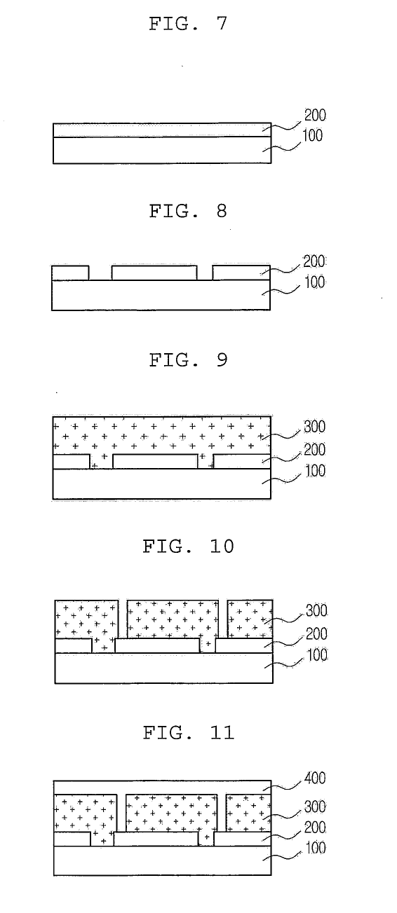

Thereafter, the solar cell layer 300 is separated into a cell unit using the laser scribing process, etc., which exposes the lower transparent electrode layer, as shown in FIG. 10.

Next, as shown in FIG. 11, the upper transparent electrode layer 400 is deposited on the solar cell layer 300 which is separated into multiple unit cells and on the lower transparent electrode layer 200 which is formed on the lower transparent substrate 100.

More specifically, the upper transparent electrode 400 is deposited through a depositing method, such as sputtering or metal organic chemical vapor deposition (MOCVD), etc. At this time, the upper transparent electrode layer 400 is formed to be electrically connected with the lower transparent electrode 200 through the intervals formed in the solar cell layer 300, and the upper transparent electrode 400 may be composed of TCO, etc., and formed at a thickness of 300 to 3000 nm.

Thereafter, as shown in FIG. 12, the upper transparent electrode 400 and the solar cell layer 300 is separated into a cell unit by a laser, etc., to complete the formation of the solar cells on the lower transparent substrate 100.

FIGS. 13 and 14 are cross-sectional views showing a process of depositing the reflective media layer 600 on the upper transparent substrate 700 and bonding reflective media layer 600 to the lower transparent substrate 100.

First, referring to FIG. 13, the reflective media layer 600 is formed on one surface (lower surface) of the upper transparent substrate 700. In one embodiment, the reflective media layer 600 may be formed using the lift-off method. That is, the separated cells can be formed by drawing cell separating lines with water ink and depositing the reflective media layer 600 by a spray method, a rolling method, etc., and then removing the water ink portions. In another embodiment, the reflective media layer 600 may be deposited on the upper transparent substrate 700 in the form of separated cells, using a screen printing method, an inkjet method, etc. Each cell of the reflective media layers 600 may be spaced at an interval of 0.5 and 2.0 mm.

At this time, the upper transparent substrate 700 may be composed of a material such as glass etc., or may be formed in a sheet form with a transparent polymer sheet such as a PET sheet, etc.

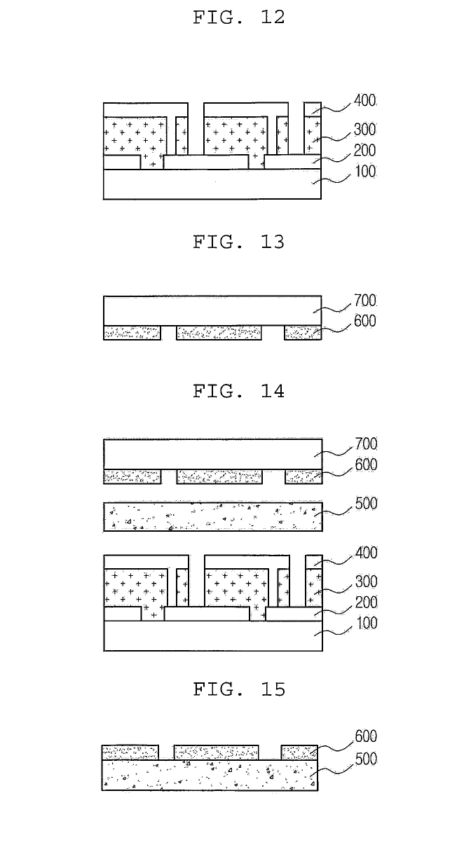

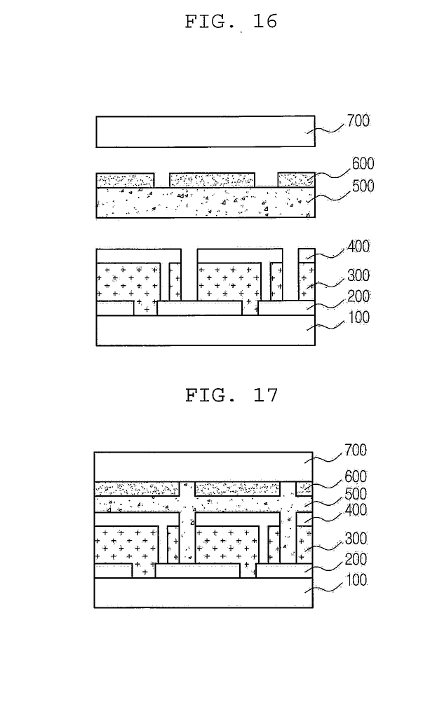

After forming the reflective media layer 600 on the upper transparent substrate 700 through the process described above, as shown in FIG. 14, the upper transparent substrate 700 and the lower transparent substrate 100 may be bonded to each other by means of the transparent adhesive layer 500, such that the solar cell module is completed as shown FIG. 15. In embodiments of the present invention, the transparent adhesive layer 500 may be located where the solar cell layer 300 is separated and/or may contact the lower transparent electrode 200.

FIGS. 15 and 16, which depict a different embodiment from FIGS. 13 and 14, are cross-sectional views showing an example that the reflective media layer 600 is formed on the transparent adhesive layer 500 in the embodiment of FIGS. 13 and 14, while the reflective media layer 600 is formed on the upper transparent substrate 700.

Referring first to FIG. 15, the reflective media layer 600 in a cell form separated using the screen printing method, the inkjet method, etc., is deposited on the transparent adhesive layer 500 and as shown in FIG. 16, the upper transparent substrate 700 and the lower transparent substrate 100 are bonded to each other by means of the transparent adhesive layer 500 on which the reflective layer 600 is formed, such that the solar cell module is completed as shown in FIG. 17.

In embodiments of the present invention, references to an upper or lower is meant to aid description of the structure of the solar cell by using a convenient frame of reference, and is just one example of a frame of reference. Accordingly, other frame of references, such as first or second is also usable.

What is claimed is:

1. A thin-film solar cell module, comprising:
a plurality of solar cells that include a lower transparent electrode layer, a solar cell layer, and an upper transparent electrode layer sequentially formed on a lower transparent substrate, the lower transparent electrode layer having portions that are spaced apart from each other at a predetermined interval;
an upper transparent substrate over the plurality of solar cells;
a reflective media layer that is formed between the plurality of solar cells and the upper transparent substrate, the reflective media layer including predetermined openings; and
a transparent adhesive layer that bonds the upper transparent substrate to the lower transparent substrate.

2. The thin-film solar cell module according to claim 1, wherein the predetermined openings of the reflective media layer are formed in an interval direction of a unit cell of the plurality of solar cells, a direction orthogonal to the interval direction, or both.

3. The thin-film solar cell module according to claim 1, wherein the predetermined openings of the reflective media layer are formed in a linear shape, a plurality of circular shapes, or a plurality of polygonal shapes.

4. The thin-film solar cell module according to claim 1, wherein the predetermined openings of the reflective media layer have an area that is 10% or less with respect to a total area of the solar cell module.

5. The thin-film solar cell module according to claim 1, wherein the reflective media layer is formed on a lower surface of the upper transparent substrate.

6. The thin-film solar cell module according to claim 1, wherein the reflective media layer is formed on an upper surface of the plurality of solar cells.

7. The thin-film solar cell module according to claim 1, wherein the upper transparent substrate is a glass substrate or a transparent polymer sheet.

8. The thin-film solar cell module according to claim 7, wherein the transparent polymer sheet is composed of polyethylene terephthalate (PET).

9. The thin-film solar cell module according to claim 1, wherein the lower transparent electrode layer and the upper transparent electrode layer are formed of transparent conductive oxide (TOC) layer composed of at least one of a zinc oxide (ZnO), tin oxide (SnO₂), and an indium tin oxide (ITO).

10. The thin-film solar cell module according to claim 1, wherein the plurality of solar cells include at least one solar cell layer composed of amorphous silicon or microcrystalline silicon.

11. The thin-film solar cell module according to claim 1, wherein the upper transparent electrode layer is formed to a thickness of about 300 to 3000 nm.

12. The thin-film solar cell module according to claim 1, wherein the reflective media layer is composed of a mixture of a media and a pigment that reflects light having a wavelength band of about 600 nm or more.

13. The thin-film solar cell module according to claim 12, wherein a difference in the refractive index between the media and the pigment is about 1.5 to 2.0.

14. The thin-film solar cell module according to claim 1, wherein the reflective media layer is formed using at least one of a white paint, a white foil and ethyl vinyl acetate (EVA).

15. The thin-film solar cell module according to claim 1, wherein the reflective media layer is a white reflective media layer.

16. The thin-film solar cell module according to claim 1, wherein the reflective media layer has a first surface which contacts with the transparent adhesive layer and a second surface which contacts with the upper transparent substrate, wherein the first surface is white and the color of the second surface is different from that of the first surface.

17. The thin-film solar cell module according to claim 1, wherein the predetermined intervals of the plurality of the solar cells are spaced with an interval of about 0.5 to 2.0 mm.

18. The thin-film solar cell module according to claim 1, wherein the transparent adhesive layer includes ethyl vinyl acetate (EVA) or polyvinyl butyral (PVB).

19. A method of manufacturing a thin-film solar cell module, the method comprising:
forming a plurality of solar cells that are spaced apart from each other at a predetermined interval on a lower transparent substrate;
forming a reflective media layer that is spaced at a predetermined interval on the plurality of solar cells; and
bonding the lower transparent substrate and an upper transparent substrate by a transparent adhesive layer with a reflective media layer between the lower transparent substrate and the upper transparent substrate.

20. The method according to claim 19, wherein the reflective media layer is formed so as to be spaced at the same predetermined interval with that of the plurality of solar cells.

21. The method according to claim 19, wherein the reflective media layer is formed in a direction orthogonal to a direction of the predetermined interval of the plurality of solar cells.

22. The method according to claim 19, wherein the reflective media layer is formed on a lower surface of the upper transparent substrate or on an upper surface of the transparent adhesive layer.

23. The method according to claim 19, wherein the reflective media layer is formed by a lift-off method, a screen printing method, or an inkjet method.
